(19) United States
(12) Patent Application Publication
(10) Pub. No.: US 2011/0052406 A1
(43) Pub. Date: Mar. 3, 2011

(54) AIRFOIL AND PROCESS FOR DEPOSITING AN EROSION-RESISTANT COATING ON THE AIRFOIL

(75) Inventors: Robert William Bruce, Loveland, OH (US); Aaron Dennis Gastrich, Cincinnati, OH (US); John William Hanify, Liberty Township, OH (US); Roger Owen Barbe, Cincinnati, OH (US)

(73) Assignee: GENERAL ELECTRIC COMPANY, Schenectady, NY (US)

(21) Appl. No.: 12/547,066

(22) Filed: Aug. 25, 2009

(51) Int. Cl. F01D 5/28; C23C 16/44

(52) U.S. Cl. 416/241 R; 427/248.1

(57) ABSTRACT

A process for depositing coatings, and particularly erosion-resistant coatings suitable for protecting surfaces subjected to collisions with particles, such as a compressor blade of a gas turbine engine. The blade has an airfoil comprising oppositely-disposed convex and concave surfaces, oppositely-disposed leading and trailing edges defining therebetween a chord length of the airfoil, and a blade tip. An erosion-resistant coating is present on at least the concave surface, but not on the convex surface within at least 20% of the chord length from the leading edge.

### BACKGROUND OF THE INVENTION

The present invention generally relates to coatings and coating processes, and more particularly to a process for depositing erosion-resistant coatings on gas turbine engine blade components having airfoil surfaces that are susceptible to erosion damage.

Gas turbines, including gas turbine engines, generally comprise a compressor, a combustor within which a mixture of fuel and air from the compressor is burned to generate combustion gases, and a turbine driven to rotate by the combustion gases leaving the combustor. Both the compressor and turbine utilize blades with airfoils against which air (compressor) or combustion gases (turbine) are directed during operation of the gas turbine engine, and whose surfaces are therefore subjected to impact and erosion damage from particles entrained in the air ingested by the engine. Gas turbine engines are particularly prone to ingesting significant amounts of particulates when operated under certain conditions, such as in desert environments where sand ingestion is likely.

Though both are attributable to ingested particles, impact damage can be distinguished from erosion damage. For the purpose of characterizing impact and erosion damage, reference will be made to the airfoil portion 12 of a compressor blade 10 depicted in FIGS. 1 and 2. Consistent with industry terminology, the airfoil 12 will be described as having leading and trailing edges 14 and 16, oppositely-disposed convex (suction) and concave (pressure) surfaces 18 and 20, a blade tip 24, and an oppositely-disposed root portion 26. The leading edge 14 is at times described as being defined by the most forward point (nose) 28 of the airfoil 12. Impact damage is primarily caused by high kinetic energy particle impacts, and typically occurs on the leading edge 14 of the airfoil 12. Traveling at relatively high velocities, particles strike the leading edge 14 or nose 28 of the airfoil 12 at a shallow angle to the concave surface 20 of the airfoil 12, such that impact with the nose 28 is head-on or nearly so. Because the airfoil 12 is typically formed of a metal alloy that is at least somewhat ductile, particle impacts can deform the leading edge 14, forming burrs that can disturb and constrain airflow, degrade compressor efficiency, and reduce the fuel efficiency of the engine.

Erosion damage is primarily caused by glancing or oblique particle impacts on the concave surface 20 of the airfoil 12, and tends to be concentrated in an area forward of the trailing edge 16, and secondarily in an area aft or beyond the leading edge 14. Such glancing impacts tend to remove material from the concave surface 20, especially near the trailing edge 16. The result is that the airfoil 12 gradually thins and loses its effective surface area due to chord length loss, resulting in a decrease in compressor performance of the engine.

Due to their location near the entrance of the engine, compressor blades suffer from both impact and erosion damage along their flowpath surfaces, particularly impact damage along their leading edges and erosion damage on their pressure (concave) surfaces. Consequently, airfoil surfaces of compressor blades are typically protected with a coating that may be deposited using various techniques, typically with a thermal spray processes such as plasma spraying and high velocity oxy-fuel (HVOF) deposition, though the use of physical vapor deposition (PVD) and chemical vapor deposition (CVD) is also employed. As known in the art, thermal spray processes generally involve the entrainment of particles in a high temperature and high velocity stream directed at a surface to be coated. The particles are sufficiently softened and deposit as “splats” to produce a coating having noncolumnar, irregular flattened grains and a degree of inhomogeneity and porosity. PVD processes such as sputtering and electron beam physical vapor deposition (EB-PVD) deposit coatings are microstructurally different from thermal spray coatings in terms of being denser and/or having columnar microstructures instead of irregular flattened grains.

The effectiveness of a protective coating on a blade is important since the blade must be removed from the engine if sufficient erosion or impact damage has occurred. Coating materials widely used to protect compressor blades are generally hard, erosion-resistant materials such as nitrides and carbides. For example, see U.S. Pat. No. 4,904,528 to Gupta et al. (titanium nitride (TiN) coatings), U.S. Pat. No. 4,839,245 to Sue et al. (zirconium nitride (ZrN) coatings), and U.S. Pat. No. 4,741,975 to Naik et al. (tungsten carbide (WC) and tungsten carbide/tungsten (WC/W) coatings). Hard coatings such as TiN have been used to alleviate damage to the surfaces of compressor blade airfoils, but the ceramic nature of these coatings makes them less capable of resisting impact damage by especially large particles impacting the coating on trajectories that are nearly perpendicular to their surfaces. An example of this is the leading edge or nose of an airfoil, where TiN is less effective. Greater impact resistance has been achieved with relatively thick coatings formed of tungsten carbide and chromium carbide (CrC and/or Cr₃C₂) applied by HVOF deposition processes to thicknesses of about 0.003 inch (about 75 micrometers). However, particles impacting at high impact angles and high impact velocities can cause the coating on the nose of the airfoil to be eroded away, after which the remaining coating on either side of the airfoil, both concave and convex, tends to retard the erosion of the adjacent metal. This problem can be very severe with thick HVOF coatings, leading to what has been termed bird beak, fish mouth, or bird mouth, and result in very unfavorable aerodynamic conditions that reduce the efficiency of the compressor. Finally, the required thickness of HVOF coatings can result in excessive weight that may negatively affect blade fatigue life (for example, high-cycle fatigue (HCF)). For these reasons, erosion-resistant coatings deposited by HVOF are often applied to only the pressure side of a blade near the blade tip.

If deposited by a PVD process such as sputtering or EB-PVD, hard erosion-resistant materials such as nitrides and carbides perform better in terms of erosion resistance when subjected to aggressive media such as crushed alumina and crushed quartz, which tend to have sharp corners and more irregular shapes than relatively round particles found in desert sands. In various tests, PVD coatings having thicknesses of about fifty micrometers and as little as about sixteen micrometers have performed favorably in comparison to HVOF coatings having thicknesses of about seventy-five micrometers. In contrast to the relatively heavy coatings deposited by HVOF, the PVD coatings are deposited on airfoil surfaces of compressor blades to have a uniform thickness. Thinner PVD coatings are less prone to the aforementioned bird beak, fish mouth, or bird mouth condition. However, the sensitivity of PVD coatings to the high impact erosion of large particles, impacting at high velocity and high impact angle, have been found to cause the degradation rate of these coatings to vary significantly in adjacent locations on the same airfoil. Nonuniform damage along the leading edge of a blade can lead to a condition called serrated leading edge, characterized by some areas of the leading edge being eroded at a rate similar to an uncoated airfoil, while adjacent areas of the leading edge appear to be in pristine condition.

A problem shared by both HVOF and PVD erosion-resistant coatings is the deterioration of the airfoil surface roughness due to erosion and particle ingestion, which if sufficiently severe can reduce the efficiency of the compressor. It is generally desirable to maintain a relatively low surface roughness, for example, about 16 microinches (about 0.4 micrometers) Ra or less.

### BRIEF DESCRIPTION OF THE INVENTION

The present invention provides a process for depositing coatings, and particularly erosion-resistant coatings suitable for protecting surfaces subjected to collisions with particles. The process is particularly well-suited for depositing a coating on a compressor blade of a gas turbine engine.

According to one aspect of the invention, a compressor blade of a gas turbine engine has an airfoil that comprises oppositely-disposed concave and convex surfaces, oppositely-disposed leading and trailing edges defining therebetween a chord length of the airfoil, a blade tip, and an erosion-resistant coating present on at least the concave surface but not on the convex surface within at least 20% of the chord length from the leading edge.

According to another aspect of the invention, a process is provided for depositing an erosion-resistant coating on a compressor blade of a gas turbine engine. The blade has an airfoil that comprises oppositely-disposed concave and convex surfaces, oppositely-disposed leading and trailing edges defining therebetween a chord length of the airfoil, and a blade tip, and the process involves placing the blade adjacent a coating material source in an apparatus configured to evaporate the coating material source and generate coating material vapors, and then depositing the erosion-resistant coating on at least the concave surface but not on the convex surface within at least 20% of the chord length from the leading edge.

A particular advantage of the process is the ability to selectively deposit a relative thin coating on the concave (pressure) airfoil surface of a blade that is prone to erosion, while avoiding the convex (suction) surface of the blade at which particle impacts can lead to unfavorable aerodynamic surface conditions if the convex surface was protected by a hard erosion-resistant coating. The invention has the further advantage of being capable of depositing thinner PVD coatings as compared to coatings deposited by thermal spray processes such as HVOF. As a result, the coatings are well suited for use as protective coatings on compressor blades of gas turbine engines without contributing excessive weight or adversely affecting desirable properties of the blades.

Other aspects and advantages of this invention will be better appreciated from the following detailed description.

### BRIEF DESCRIPTION OF THE DRAWINGS

FIG. 1 is a side view of a compressor blade, and FIG. 2 is a cross-sectional view along section line 2-2 of FIG. 1.

FIG. 3 schematically represents a blunted leading edge of a blade resulting from impact and erosion damage.

FIG. 4 schematically represents a blunted leading edge of a blade resulting from impact and erosion damage, but exhibiting a more aerodynamically favorable profile than the blade of FIG. 3.

FIG. 5 schematically contrasts the blunted leading edges of FIGS. 3 and 4.

FIGS. 6, 7 and 8 are scanned images of three compressor blades provided with erosion-resistant coatings and subjected to erosion testing.

FIG. 9 is a scanned image showing a cross-section of the blade of FIG. 7.

FIG. 10 is a scanned image showing a cross-section of the blade of FIG. 8.

FIG. 11 is a scanned image showing a cross-section of the blade of FIG. 6.

FIG. 12 is a scanned image showing a cross-section of the blade of FIG. 7 taken at a different span location than the image of FIG. 9.

FIG. 13 is a scanned image showing a cross-section of the blade of FIG. 8 taken at a different span location than the image of FIG. 10.

FIG. 14 is a scanned image showing a cross-section of the blade of FIG. 6 taken at a different span location than the image of FIG. 11.

FIGS. 15 and 17 are scanned images, each showing two cross-sections of two different compressor blades in an as-coated condition.

FIGS. 16 and 18 are scanned images, each showing two cross-sections of two different compressor blades similar to FIGS. 15 and 17 following an erosion test.

FIG. 19 is a graph plotting the aerodynamic performance of a compressor blade provided with an erosion-resistant coating applied in accordance with an embodiment of this invention and similar compressor blades provided with erosion-resistant coatings applied in accordance with the prior art.

FIG. 20 schematically represents a planetary tool suitable for depositing an erosion-resistant coating in accordance with an embodiment of this invention.

### DETAILED DESCRIPTION OF THE INVENTION

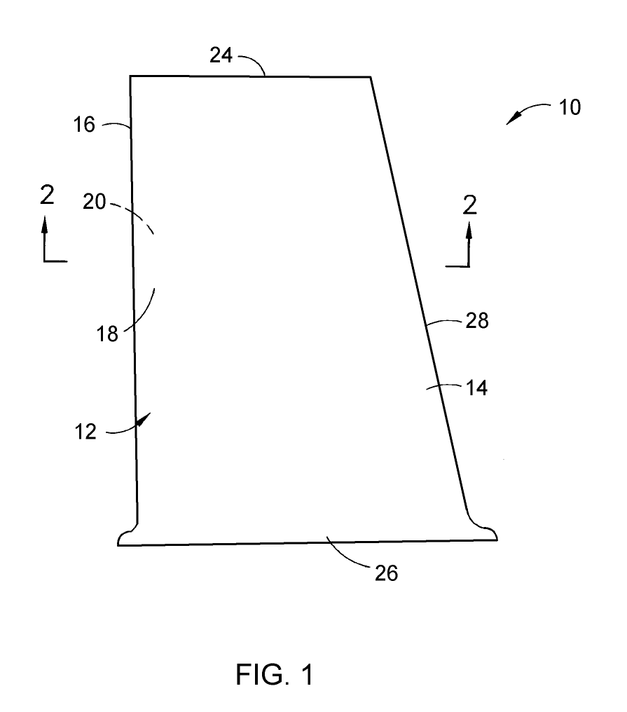

As previously described, FIGS. 1 and 2 represent the airfoil 12 of a gas turbine engine compressor blade 10. The present invention is particularly well suited for compressor blades of aircraft gas turbine engines, but is applicable to airfoil components used in other applications.

The blade 10 is formed of a material that can be formed to the desired shape and withstand the necessary operating loads at the intended operating temperatures of the gas turbine compressor in which the blades will be installed. Examples of such materials include metal alloys that include, but are not limited to, titanium-, aluminum-, cobalt-, nickel-, and steel-based alloys. When the blade 10 is installed in the compressor section of a gas turbine engine, the convex (suction) and concave (pressure) surfaces 18 and 20 of the blade 10 define what will be termed herein flowpath surfaces, in that they are directly exposed to the air drawn through the engine. The flowpath surfaces of the blade 10 are subject to impact and erosion damage from particles entrained in the ingested air. In particular, the leading edges 14 of the blade 10 are susceptible to impact damage from particles ingested into the engine, whereas the concave (pressure) surface 20 of the blade 10 is prone to erosion damage, particularly forward of the trailing edge 16, aft or beyond the leading edge 14, and near the blade tip 24. As will be explained below, a particular aspect of the invention is that impact and erosion damage can be minimized and aerodynamically favorable surface conditions can be better maintained by applying an erosion-resistant ceramic coating to only the concave surface 20 and nose 28 of the blade 10, and more preferably only the concave surface 20 of the blade 10.

The coating may be entirely composed of one or more ceramic compositions, and may be bonded to the blade substrate with a metallic bond coat. For example, in accordance with the teachings of commonly-assigned U.S. patent application Ser. No. 12/201,566 to Bruce et al., the ceramic coating may contain one or more layers of TiAlN, multiple layers of CrN and TiAlN in combination (for example, alternating layers), and one or more layers of TiSiCN, without any metallic interlayers between the ceramic layers. Such ceramic coatings preferably have a thickness of greater than sixteen micrometers, for example, about twenty-five to about one hundred micrometers. Coating thicknesses exceeding one hundred micrometers are believed to be unnecessary in terms of protection, and undesirable in terms of additional weight. If the ceramic coating is made up of TiAlN, the entire coating thickness can consist of a single layer of TiAlN or multiple layers of TiAlN, and each layer may have a thickness of about twenty-five to about one hundred micrometers. If the ceramic coating is made up of multiple layers of CrN and TiAlN, each layer may have a thickness of about 0.2 to about 1.0 micrometers, for example, about 0.3 to about 0.6 micrometers, to yield a total coating thickness of at least about three micrometers. If the ceramic coating is made up of TiSiCN, the entire coating thickness can consist of a single layer of TiSiCN or multiple layers of TiSiCN, and each layer may have a thickness of about fifteen to about one hundred micrometers. Other coatings, coating compositions, and coating thicknesses are also within the scope of the invention.

If a metallic bond coat is employed, the bond coat may be made up of one or more metal layers, for example, one or more layers of titanium and/or titanium aluminum alloys, including titanium aluminide intermetallics. The bond coat can be limited to being located entirely between the ceramic coating and the substrate it protects for the purpose of promoting adhesion of the ceramic coating to the substrate.

Coatings of this invention are preferably deposited by a physical vapor deposition (PVD) technique, and therefore will generally have a columnar and/or dense microstructure, as opposed to the noncolumnar, irregular, and porous microstructure that would result if the coating were deposited by a thermal spray process such as HVOF. Particularly suitable PVD processes include EB-PVD, cathodic arc PVD, and sputtering, with cathodic arc believed to be preferred. Suitable sputtering techniques include but are not limited to direct current diode sputtering, radio frequency sputtering, ion beam sputtering, reactive sputtering, magnetron sputtering, plasma-enhanced magnetron sputtering, and steered arc sputtering. Cathodic arc PVD and plasma-enhanced magnetron sputtering are particularly preferred for producing coatings due to their high coating rates. Depending on the coating composition to be deposited, deposition can be carried out in an atmosphere containing a source of carbon (for example, methane), a source of nitrogen (for example, nitrogen gas), or a source of silicon and carbon (for example, trimethylsilane, (CH₃)₃SiH) to form carbide, silicon, and/or nitride constituents of the deposited coating. The metallic bond coat and any other metallic layers are preferably deposited by performing the coating process in an inert atmosphere, for example, argon.

The coating is preferably deposited to have a surface roughness in the airflow direction of about 16 microinches (about 0.4 micrometers) Ra or less. The blade may undergo polishing to achieve this surface finish. Polishing of the airfoil can be performed before coating deposition to promote the deposition of a smooth coating, with additional polishing performed after coating deposition to ensure the desired surface roughness is obtained. Polishing can also be performed as an intermediate step of the coating process.

According to a preferred aspect of the invention, the difficulty of maintaining a relatively low surface roughness, for example, about 20 microinches (about 0.5 micrometers) Ra or less, over an extended time during the operation of the gas turbine engine is addressed in part on the determination that certain airfoil regions suffer impact and/or erosion damage that is more detrimental to aerodynamic performance if the damage occurs to a hard erosion-resistant coating than to the blade substrate. In other words, the present invention proposes that certain airfoil regions of the blade 10 (FIG. 1) are selectively coated while others are not to achieve impact and erosion characteristics that promote the aerodynamic performance of the blade 10, and in particular low surface roughnesses, based on airfoil regions being prone to different types of damage with different effects on the aerodynamic performance of the blade 10.

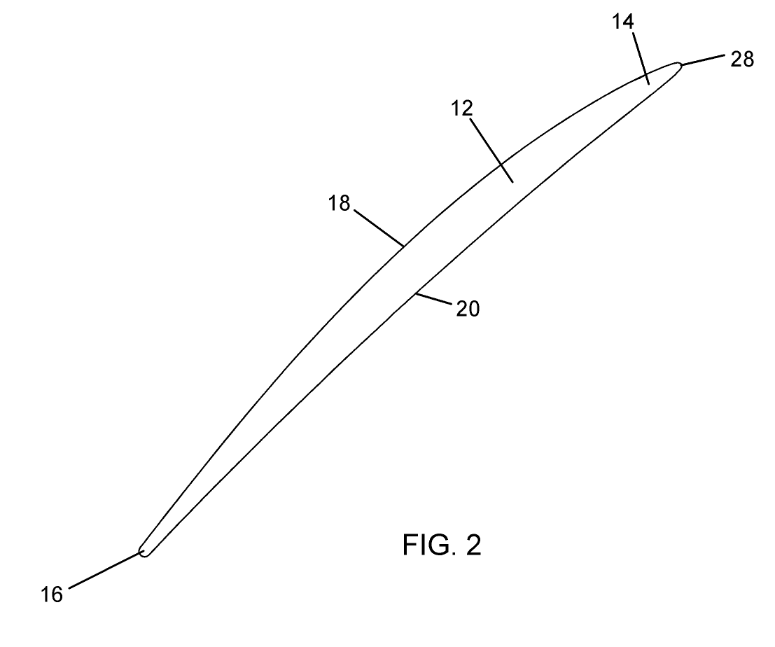

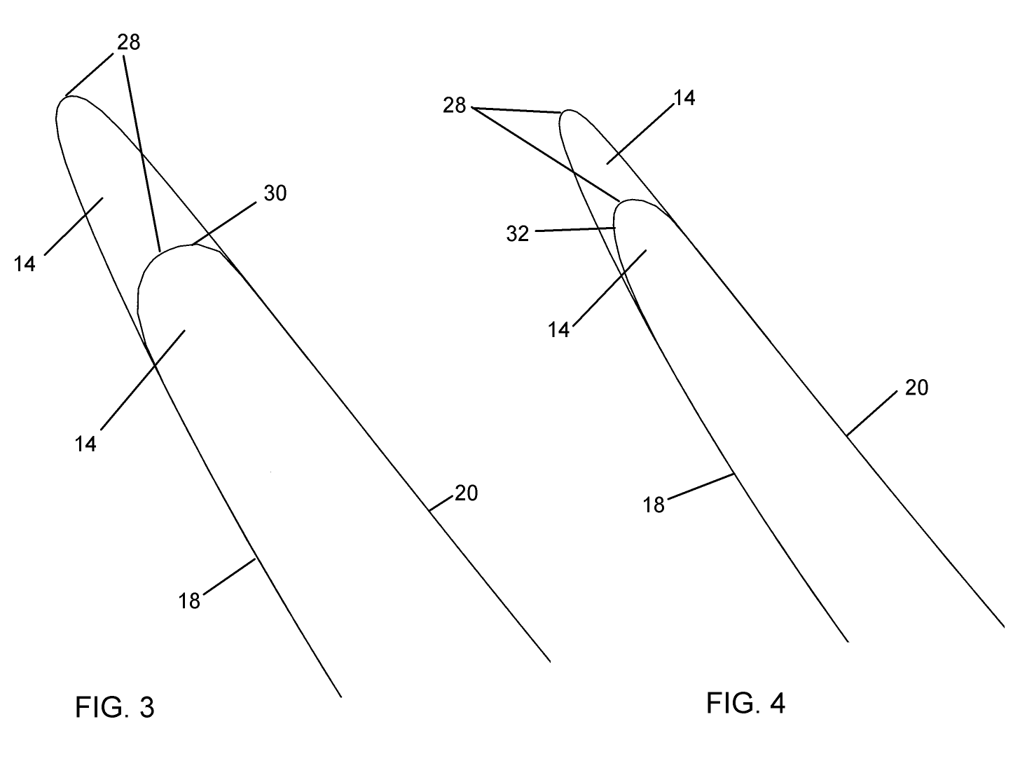

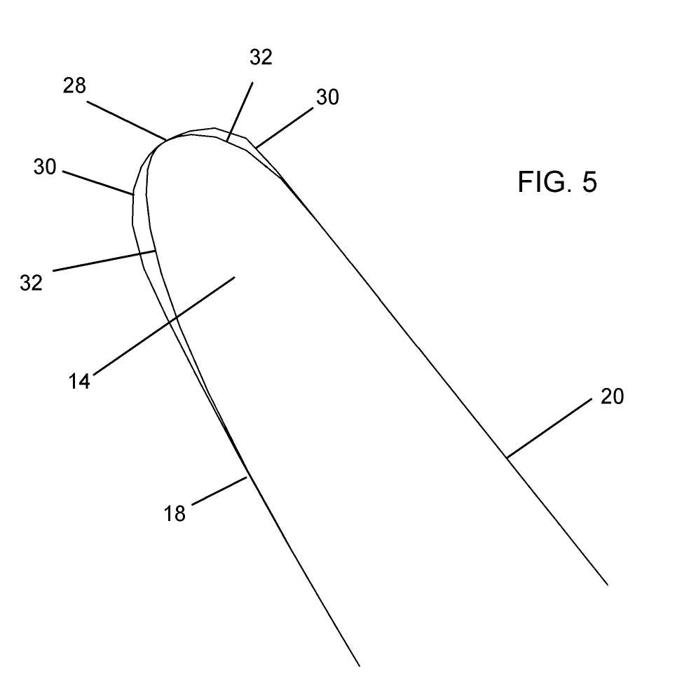

The types of damage of particular interest are blunting of the leading edge 14 and serration of the leading edge 14 and nose 28 of the blade. Typically blunting observed on the leading edge 14 of an airfoil 12 protected by a PVD erosion-resistant coating is represented in FIG. 3 as a significant loss of chord length due to erosion of the airfoil leading edge 14, leading to a rounder profile 30 that the original leading edge 14 (shown in phantom). While damage characterized as the aforementioned bird beak, fish mouth, or bird mouth conditions are of concern, particularly in reference to airfoils protected by HVOF erosion-resistant coatings, it is believed that blunting and serration are more detrimental than increased surface roughness and decreased chord length of an airfoil 12 protected by a PVD erosion-resistant coating. Accordingly, one aspect of the invention is to maintain a profile at the leading edge 14 having a smoother and more gradual transition to the convex and concave surfaces 18 and 20 as the leading edge 14 deteriorates from erosion and particle impact. Such a profile 32 is represented in FIG. 4, and contrasted in FIG. 5 with the more blunt profile 30 of FIG. 3. Another preferred though likely lesser aspect is to reduce the incidence or degree of leading edge serration, whose progression is the result of surface deterioration by localized impact and erosion irregularities.

The present invention addresses blunting of the leading edge 14 by avoiding the deposition of erosion-resistant coating on the convex surface 18 of the airfoil 12, and optionally addresses serration of the leading edge 14 by further avoiding the deposition of erosion-resistant coating on the nose 28 of the airfoil 12. As a result, the deterioration of the airfoil leading edge 14, convex surface 18, and nose 28 is similar to that of an uncoated airfoil, which progresses more rapidly than would occur if these surfaces were protected with an erosion-resistant coating, but progresses more uniformly to maintain a relative smooth leading edge profile during deterioration. These remedies were the result of experimentation described below, which evidenced the effects of different coating coverages on the erosion resistance of compressor blades of the CFM56-7 gas turbine engine, manufactured by the General Electric Company.

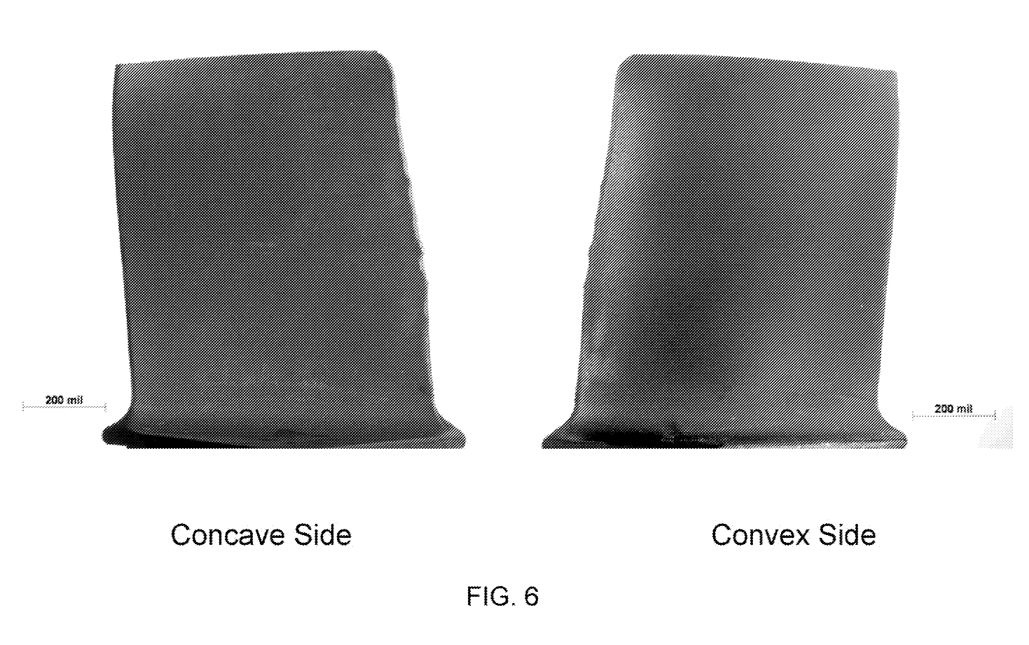

FIGS. 6, 7 and 8 are scanned images of three Stage 7 high pressure compressor (HPC) blades of the CFM56-7 that were coated with an erosion-resistant coating system and underwent a sand engine erosion test on the same test stand. Three different coating systems were used in the investigation: alternating layers of CrN and TiAlN, TiSiCN, and TiAlN, without any metallic interlayers between the ceramic layers.

The blade shown in FIG. 6 is designated as being coated with a “PVD Coating A,” made up of alternating layers of CrN and TiAlN preferentially deposited on the concave surface of the blade. The coating had an original coating thicknesses of about 30 micrometers or more on the concave surface of the blade and an original coating thickness on the convex and nose surfaces of less than 35% of the coating thickness on the concave surface and more typically less than 25% of the coating thickness on the concave surface. The coating thickness on the nose was less than the coating thickness on the convex surface.

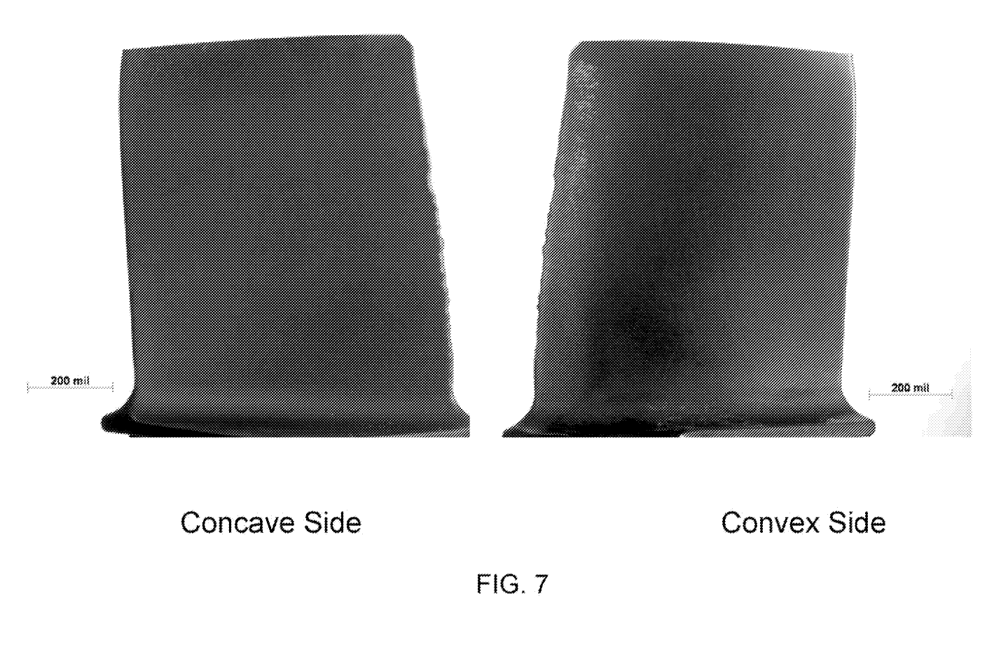

The blade shown in FIG. 7 is designated as being coated with a “PVD Coating B,” formed of TiSiCN and preferentially deposited on the concave surface of the blade. The coating had an original coating thickness of about 22 micrometers or more on the concave and nose surfaces of the blade and an original coating thickness on the convex surface of at least 25% to about 50% of the coating thickness on the concave surface. As such, the “B” blade generally had a thicker coating on its convex and nose surfaces than the “A” blade, and the coating thickness on the nose was greater than the coating thickness on the convex surface.

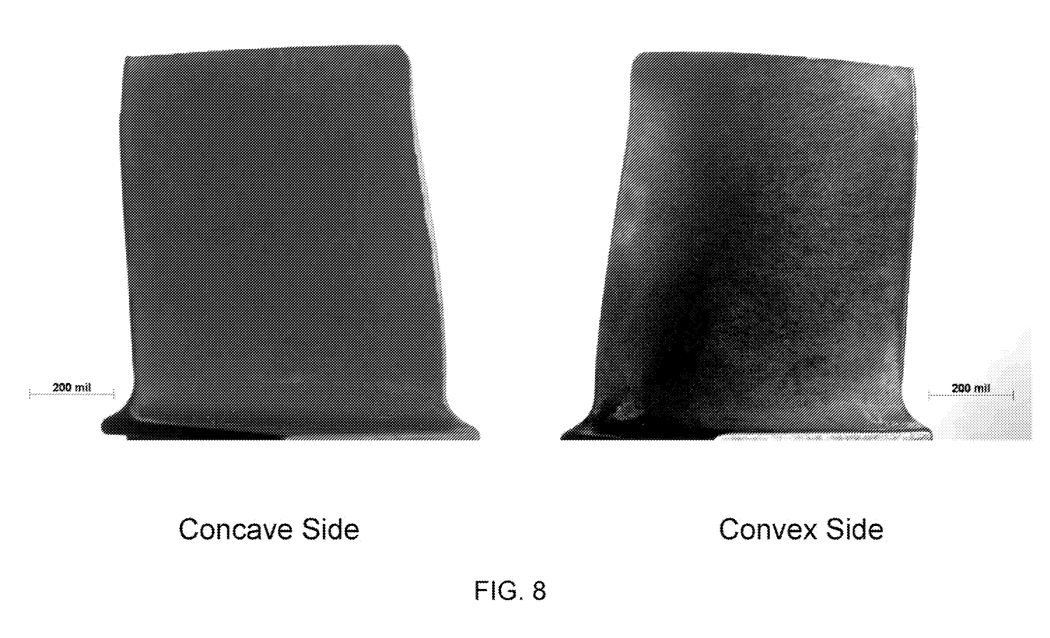

The blade shown in FIG. 8 is designated as being coated with a “PVD Coating C,” formed of TiAlN and deposited on all surfaces of the blade, though thinner at the leading edge and nose. The coating had an original coating thickness of about 30 micrometers or more on the concave and nose surfaces of the blade and an original coating thickness on the convex surface of greater than 50% and up to 120% of the coating thickness on the concave surface. As such, the “C” blade generally had a thicker coating on its convex and nose surfaces than the “A” and “B” blades. Furthermore, the coating thickness on the nose was typically greater than the coating thickness on the convex surface.

The “A” and “B” blades in FIGS. 6 and 7 can be seen to have serrated leading edges, whereas the leading edge of the “C” blade in FIG. 8 is much smoother. However, what is not readily evident from the blades of FIGS. 7 and 8 is that their blade leading edges suffered significantly more damage from blunting than did the blade of FIG. 6.

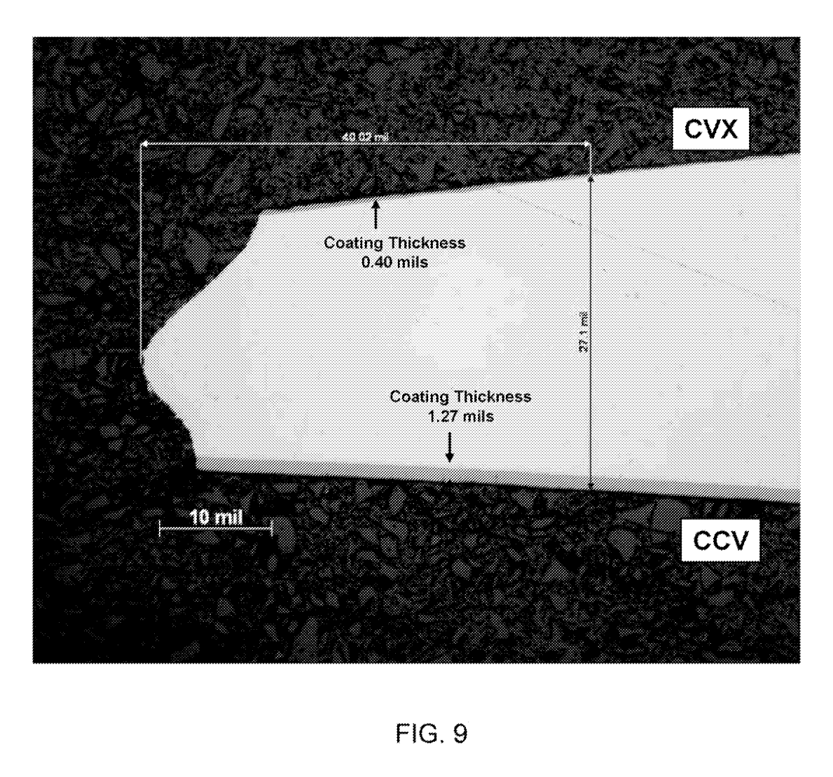

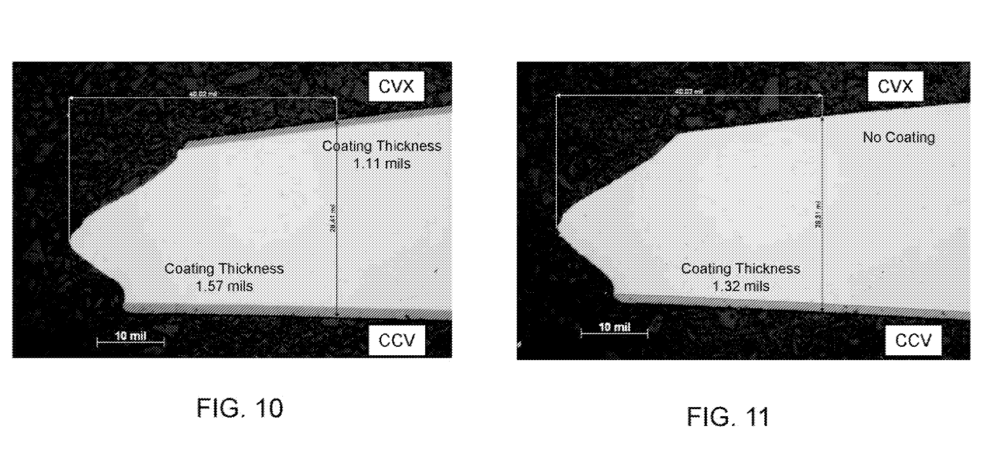

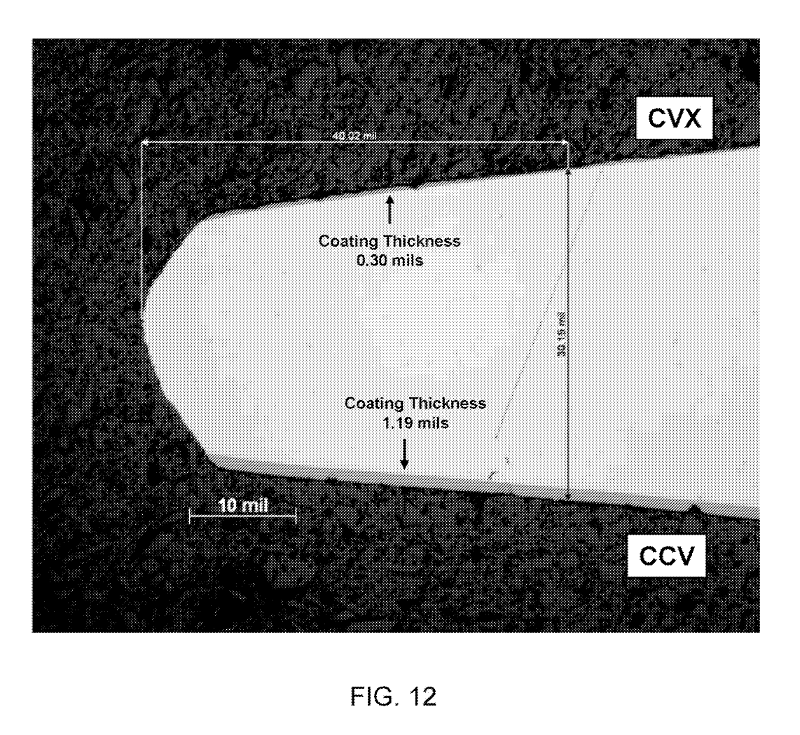

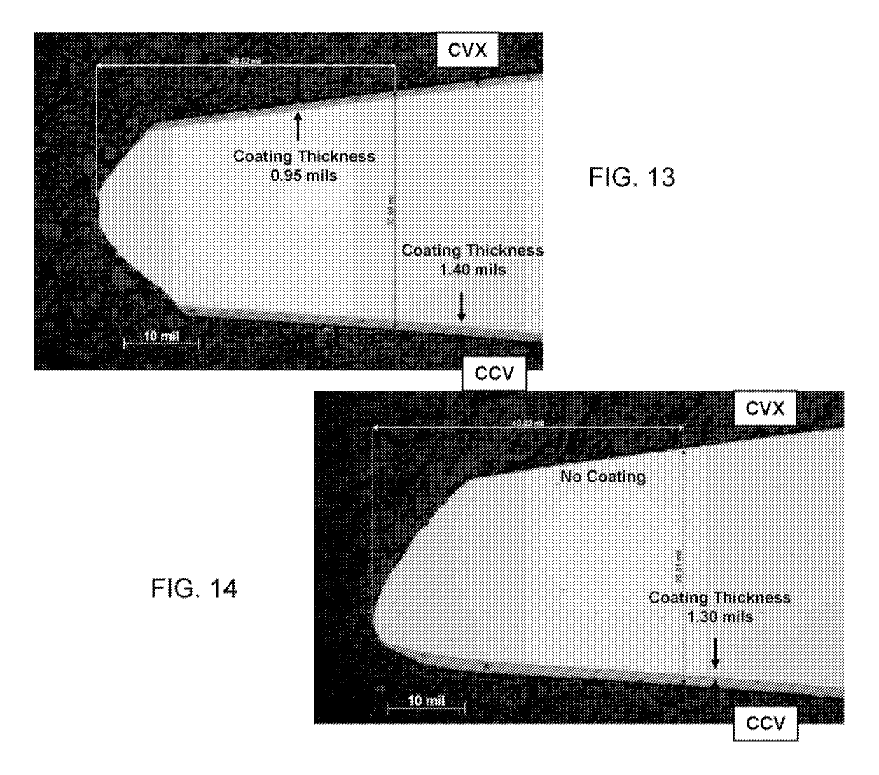

FIG. 9 is a photomicrograph of a cross-section at the leading edge of the “B” blade at about 71% of the span length of the blade, and evidences that the leading edge and nose of the blade suffered considerable damage from blunting. Notably, a cusp can be seen as having been formed at the intersection of the blunted leading edge and the convex surface. A similar section of the “C” blade is shown in FIG. 10, in which blunting of the blade leading edge is not as extensive as the “B” blade, though again a cusp is clearly defined at the intersection of the blunted leading edge and the convex surface of the blade. Finally, a similar section of the “A” blade in FIG. 11 shows leading edge blunting similar to the “C” blade, but with a reduced cusp at the intersection of the leading edge and convex surface of the blade. Aerodynamic analysis showed that blunting and the cusp formation seen in FIGS. 9 and 10 have a significant negative effect on airfoil efficiency, more so than the serrated leading edges of the “A” and “B” blades seen in FIGS. 6 and 7 to the extent that the presence of the serrated leading edge of the “A” blade in FIG. 6 is believed to be a lesser issue in the absence of blunting and cusp seen in FIGS. 7 and 8. FIGS. 12 and 13 are cross-sections at the leading edges of the “B” and “C” blades at about 40% of the span length of the blades, and evidence even greater leading edge blunting, though without the well-defined cusp seen in FIGS. 9 and 10. In contrast, the significantly more gradual transition from the nose to the convex surface of the “A” blade in FIG. 14 evidences a more aerodynamic shape for a compressor blade. On the basis of the above, the “A” blade of FIG. 6 was concluded to be aerodynamically superior to the “B” and “C” blades of FIGS. 7 and 8.

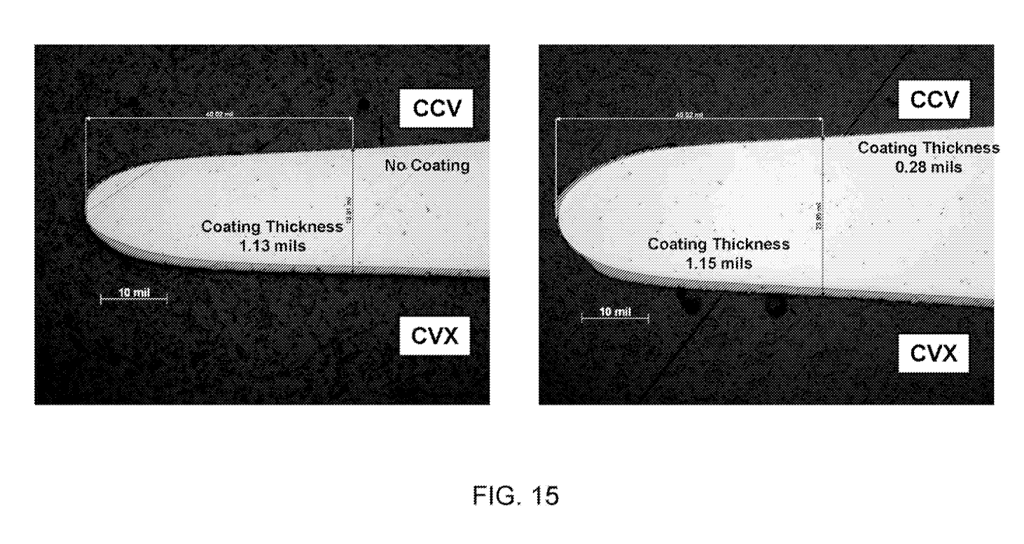

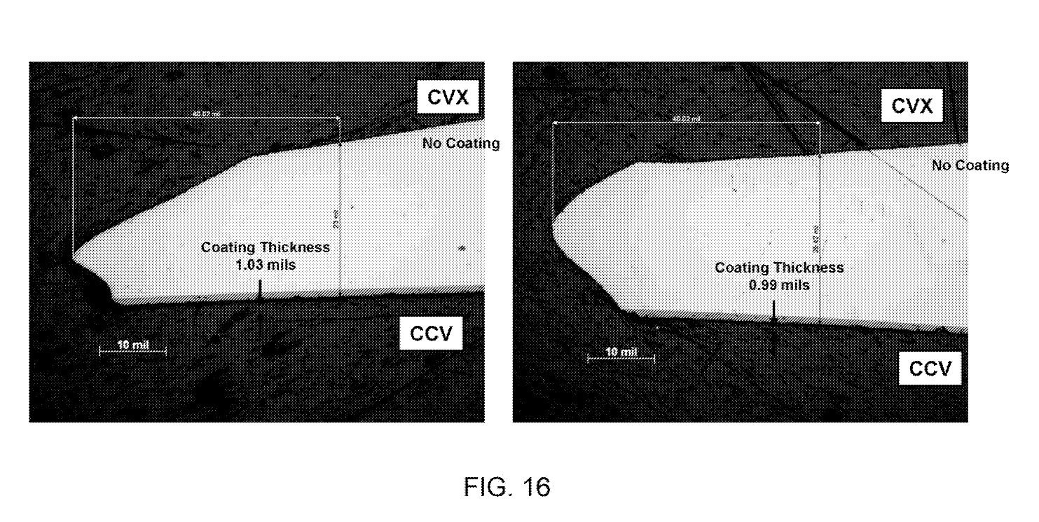

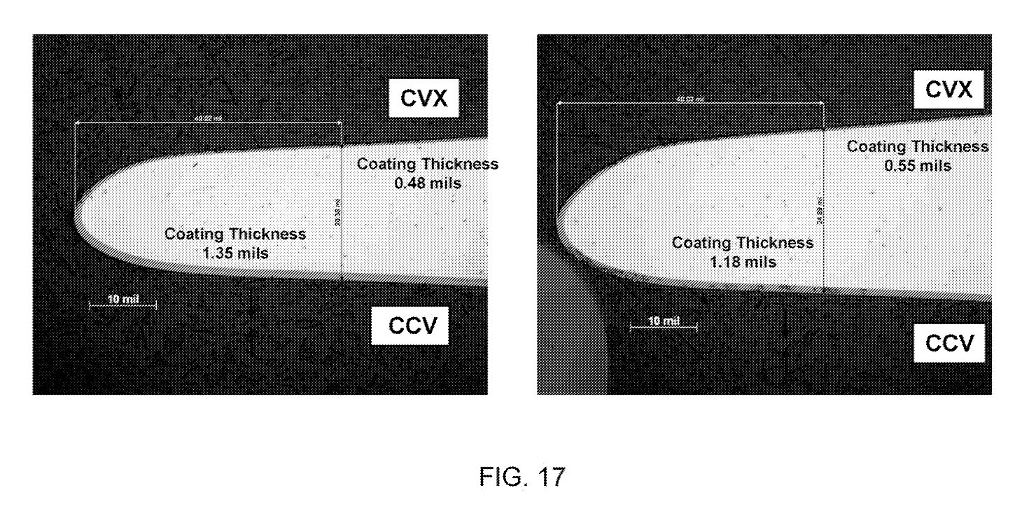

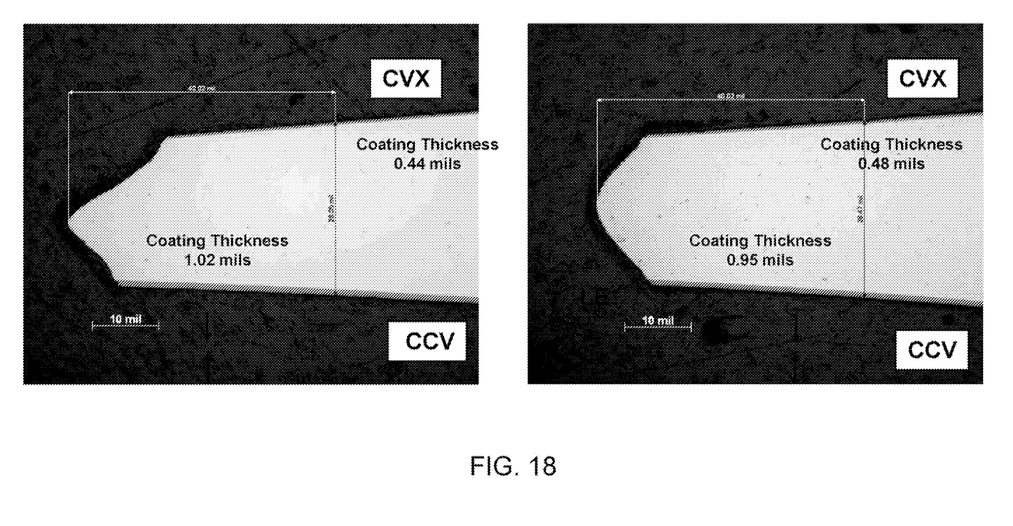

FIGS. 15 and 17 are scanned images of two Stage 9 high pressure compressor blades of the CFM56-7 that were coated with the same erosion-resistant coating as the Stage 7 blades of FIGS. 6 through 14, and FIGS. 16 and 18 are scanned images of two essentially identical Stage 9 high pressure compressor blades that underwent the same sand engine erosion test as the Stage 7 blades. FIGS. 15 and 16 are blades coated in accordance with the previously described “A” blade coating coverage, whereas FIGS. 17 and 18 are blades coated in accordance with the previously described “B” blade coating coverage. Each of FIGS. 15 through 17 show sections taken at the 39% and 71% span of the blade. In comparing FIGS. 16 and 18, the leading edges of both blades can be seen to have suffered blunting at their leading edges. However, the sections of the “A” blade in FIG. 16 evidence less severe blunting than the “B” blade of FIG. 18, the absence of the pronounced cusp seen at the intersection of the leading edge and convex surface of the blade in FIG. 18, and a significantly more gradual transition from the leading edge to the convex surface of the “A” blade in FIG. 16, corresponding to a more aerodynamic shape. On this basis, it was again concluded that the coating coverage of the “A” blade is aerodynamically superior to the coating coverage of the “B” blade.

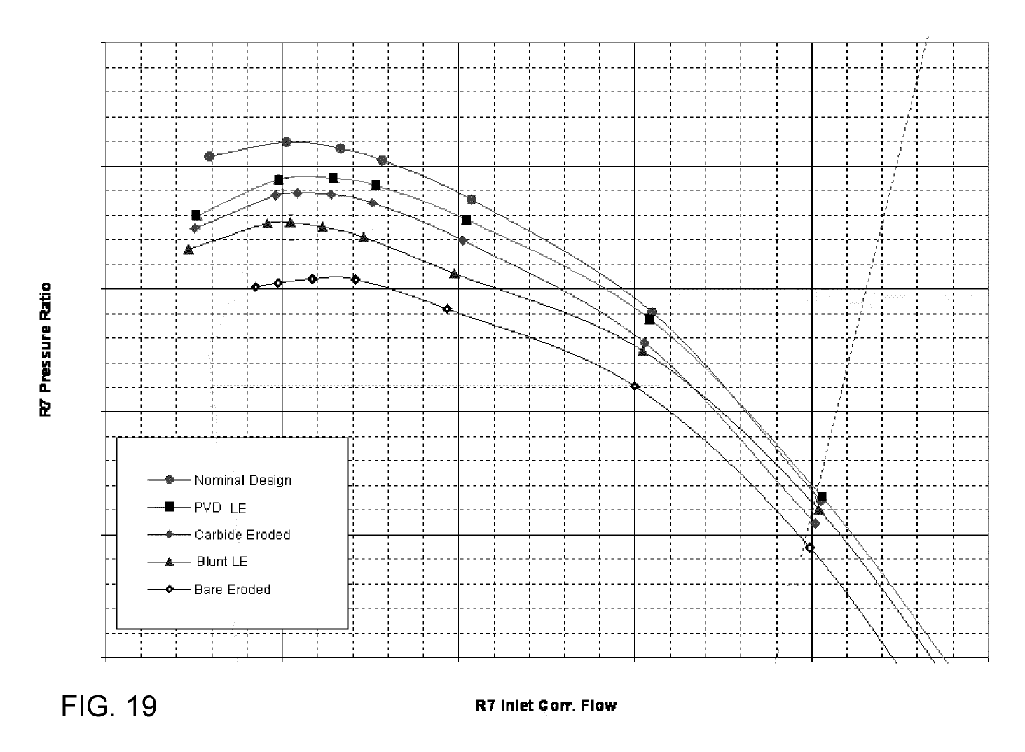

FIG. 19 is a graph plotting the pressure ratio versus inlet corrected flow for four Stage 7 HPC blades against a nominal design standard for Stage 7 HPC blades of the CFM56-7 gas turbine engine. All four blades were formed of IN718, a nickel-base superalloy having a nominal composition of, by weight, 50-55% nickel, 17-21% chromium, 2.8-3.3% molybdenum, 4.75-5.5% niobium, 0-1% cobalt, 0.65-1.15% titanium, 0.2-0.8% aluminum, 0-0.35% manganese, 0-0.3% copper, 0.08% maximum carbon, 0.006% maximum boron, the balance iron. Three of the blades had been coated while the fourth was uncoated (“Bare Eroded”) prior to undergoing a sand engine erosion test. One of the blades identified as “PVD LE” was provided with a coating of alternating layers of CrN and TiAlN preferentially deposited on the concave surface of the blade, consistent with the coating coverage consistent of the “A” blade described above. In particular, the blade had a coating thickness of about 31 micrometers on its concave surface, a coating thickness of about 10 micrometers on its convex surface, and a coating thickness of about 7 micrometers on its nose. A second of the blades identified as “Carbide Eroded” was provided with a Cr₃C₂NiCo carbide coating having a thickness of about 75 micrometers on its concave surface only. A third blade is identified as “Blunt LE,” and was provided with a TiAlN coating having a coating thickness of about 40 micrometers on its concave surface, a coating thickness of about 40 micrometers on its convex surface, and a coating thickness of about 40 micrometers on its nose. The data plotted in FIG. 19 were generated by an aerodynamic code, and evidence the aerodynamic superiority of the PVD LE blade in comparison to the remaining blades. The performance of the “Bare Eroded” blade was attributable to significant loss of chord length as a result of blunting/loss at the leading and trailing edges of the blade. The “Carbide Eroded” blade also experienced significant trailing edge erosion leading to a loss of chord length. In contrast, the damage to the “Blunt LE” blade was largely blunting of the leading edge of the blade, which was sufficient to reduce the aerodynamic performance of the “Blunt LE” blade to less than that of the “Carbide Eroded” blade. The data of FIG. 19 again evidenced that a compressor blade protected at only its concave surface can be aerodynamically superior to an identical blade protected on its concave, convex and nose surfaces with the same erosion-resistant coating and subjected to the same impact/erosion conditions.

On the basis of the above results, it was concluded that a suitable thickness for a PVD erosion-resistant coating on the concave surface of a compressor airfoil is at least 16 micrometers, for example, 25 to 100 micrometers. A preferred coating thickness for the nose 28 of the airfoil 12 is believed to be less than 20 micrometers or less than 30% of the coating thickness on the concave surface 20 of the airfoil 12, whichever is less, and a preferred coating thickness for the convex surface 18 of the airfoil 12 is less than 10 micrometers or less than 20% of the coating thickness on the concave surface 20 of the airfoil 12, whichever is less. The selective deposition of the erosion-resistant coating can be achieved at least in part by exposing only the concave surface 20 of the airfoil 12 to the coating flux generated during a PVD process. Exposure of the convex surface 18 of the airfoil 12 to the coating flux is preferably avoided, and exposure of the nose 28 of the airfoil 12 to the coating flux is preferably minimized if not entirely avoided. In particular, it is preferred to prevent the deposition of coating on the portion of the convex surface 18 within at least 20% of the chord length from the nose 28. Though avoiding/minimizing the deposition of coating on the convex surface 18 and especially the nose 28 is expected to allow for leading edge erosion at a rate similar to that of an uncoated airfoil, better overall aerodynamic performance is believed to be maintained as a result of smoother transition from the coating-free nose 28 to the coating-free convex surface 18. The presence of the PVD erosion-resistant coating on the concave surface 20 and the trailing edge 16 of the airfoil 12 are believed to be sufficient to maintain an adequate chord length of the airfoil 12.

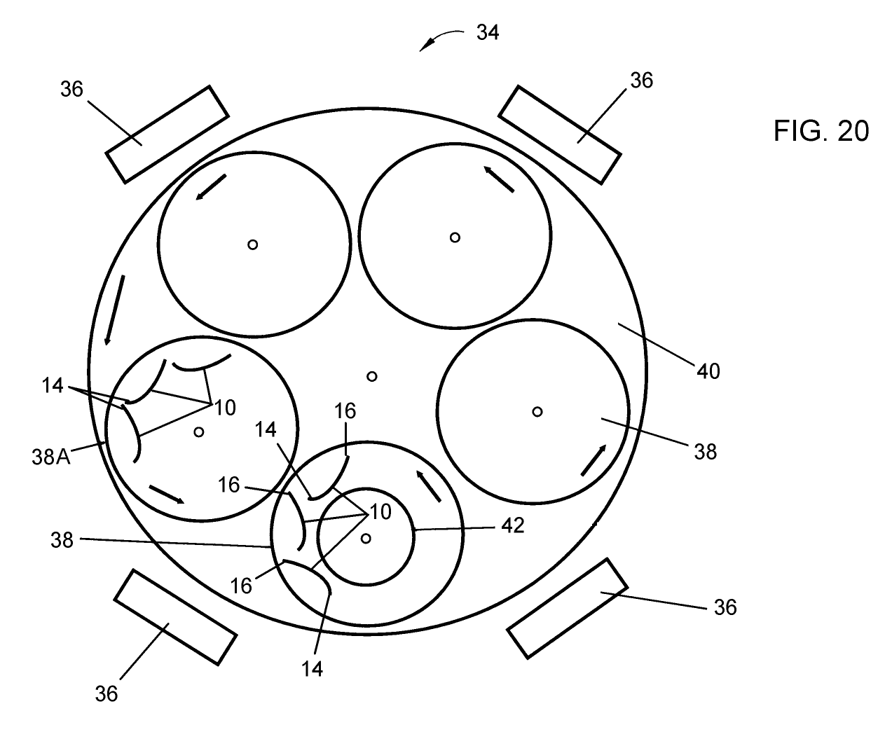

Selective deposition of the erosion-resistant coating can be accomplished by a motion arrangement during coating that minimizes exposure of the convex surface 18 and leading edge 14 of the airfoil 12 to the flux during the coating deposition process. For example, FIG. 20 depicts a technique by which blades 10 can be positioned on planetary tooling 34 to shield the leading edges 14 and convex surfaces 18 of their airfoils 12 from the coating vapor flux. FIG. 20 is a plan view showing multiple blades 10 mounted on the planetary tooling 34 so that each blade 10 is oriented with its longitudinal (span-wise) axis perpendicular to a linear path between the blade 10 and a source 36 of the coating material, such as sputter targets. Each blade is mounted on a planetary 38 for rotation about its longitudinal axis, while also being rotated on a carousel 40 relative to the coating material sources 36. On one of the planetaries 38, the leading edges 14 and convex surfaces 18 are positioned behind the trailing edges 16 of adjacent airfoils 12, and a mask 42 is positioned at the center of each rotating set of airfoils 12 to prevent coating flux from passing through the airfoils 12 remote from the nearest source 36. The same configuration can be employed for each of the remaining planetaries 38 of the tooling 34. For comparison, one planetary 3 8A is represented with blades 10 mounted in a conventional manner to allow deposition of coating on all surfaces of the blades 10.

Alternatively or in addition, physical shields or masks could be used to prevent deposition on the convex surfaces 18 of the airfoils 12 and optionally prevent or at least minimize deposition on the leading edges 14 of the airfoils 12. Also alternatively or in addition, the planetary unit 34 could provide cammed rotation of the airfoils 12 during coating to provide slow rotation when the concave surfaces 20 are exposed for coated, and fast rotation when the convex surfaces and noses of the airfoils 12 are exposed to the coating material sources 36. Still other options include locally stripping the coating from the convex surface 18 and nose 28 of the airfoils 12 after coating, and minimizing the adhesion of the coating at the convex surface 18 and nose 28 so that the coating will rapidly erode from the convex surface 18 and nose 28.

Preferably, the airfoil and coating are processed to obtain a surface roughness at 16 microinches (about 0.4 micrometer) Ra or less. The convex and concave surfaces 18 and 20 of the airfoil 12 can be polished before coating deposition, after coating deposition, and/or as an intermediate step of the coating process. The smoothness of the coating can be promoted by ensuring that the PVD coating chamber is clean to avoid the deposition of dust and particles during the evaporation process, and minimizing spits during the evaporation process, by which solid particles from the target are deposited on the airfoil surface as the result of an eruption of a molten region of the target. Other and additional surface preparations can be performed on the blade 10, including peening, degreasing, heat tinting, grit blasting, back sputtering, etc., to attain desirable surface conditions.

It is foreseeable that additional measures could be taken to reduce the deterioration rate of the erosion-resistant coating and the uncoated airfoil surfaces, and/or to ensure that the deterioration of the coating and airfoil surfaces progresses in a manner that maintains a relatively smooth surface finish. For example, coating chemistry and deposition parameters that affect coating density, strength, and elastic modulus could be effectively used for this purpose, as could be the choice of material for the airfoil substrate. Still other methods may be used to promote a low surface roughness for the coating and minimize the coating thickness and/or adhesion to the convex surface 18 and nose 28 of the airfoil 12.

While the invention has been described in terms of specific embodiments, it is apparent that other forms could be adopted by one skilled in the art. Therefore, the scope of the invention is to be limited only by the following claims.

1. A compressor blade of a gas turbine engine, the blade having an airfoil that comprises oppositely-disposed convex and concave surfaces, oppositely-disposed leading and trailing edges defining therebetween a chord length of the airfoil, a forward-most nose of the airfoil located at the leading edge, a blade tip, and an erosion-resistant coating present on at least the concave surface but not on the convex surface within at least 20% of the chord length from the nose.

2. The compressor blade according to claim 1, wherein the erosion-resistant coating has a thickness of greater than 16 to about 100 micrometers on the concave surface.

3. The compressor blade according to claim 1, wherein the erosion-resistant coating is not present on the convex surface of the airfoil.

4. The compressor blade according to claim 3, wherein the erosion-resistant coating is not present on the nose of the airfoil.

5. The compressor blade according to claim 1, wherein the erosion-resistant coating is not present on the nose of the airfoil.

6. The compressor blade according to claim 1, wherein the erosion-resistant coating is present on the nose of the airfoil.

7. The compressor blade according to claim 6, wherein the erosion-resistant coating has a thickness on the nose of the airfoil of less than 20 micrometers or less than 30% of the coating thickness on the concave surface of the airfoil, whichever is less.

8. The compressor blade according to claim 1, wherein the erosion-resistant coating is present on the convex surface of the airfoil.

9. The compressor blade according to claim 8, wherein the erosion-resistant coating has a thickness on the convex surface of the airfoil of less than 10 micrometers or less than 20% of the coating thickness on the concave surface of the airfoil, whichever is less.

10. The compressor blade according to claim 1, wherein the erosion-resistant coating entirely covers the concave surface and the trailing edge of the airfoil.

11. The compressor blade according to claim 1, wherein the erosion-resistant coating contains at least one layer having a composition chosen from the group consisting of TiAlN, CrN, and TiSiCN.

12. A method of depositing the erosion-resistant coating according of claim 1, the method comprising depositing the ceramic coating by a physical vapor deposition process.

13. A compressor blade of a gas turbine engine, the blade having an airfoil that comprises oppositely-disposed convex and concave surfaces, oppositely-disposed leading and trailing edges defining therebetween a chord length of the airfoil, a forward-most nose of the airfoil located at the leading edge, a blade tip, and an erosion-resistant coating having a thickness of greater than 16 to about 100 micrometers on the concave surface and the trailing edge of the airfoil, the erosion-resistant coating optionally being present on the nose of the airfoil and having a thickness thereon of less than 20 micrometers or less than 30% of the coating thickness on the concave surface of the airfoil, whichever is less, and the erosion-resistant coating optionally being present on the convex surface of the airfoil and having a thickness thereon of less than 10 micrometers or less than 20% of the coating thickness on the concave surface of the airfoil, whichever is less, the convex surface being free of the erosion-resistant coating within at least 20% of the chord length from the nose.

14. The compressor blade according to claim 13, wherein the erosion-resistant coating is not present on the convex surface of the airfoil.

15. The compressor blade according to claim 13, wherein the erosion-resistant coating is not present on the nose of the airfoil.

16. A method of depositing the erosion-resistant coating according of claim 13, the method comprising depositing the ceramic coating by a physical vapor deposition process.

17. A process of depositing an erosion-resistant coating on a compressor blade of a gas turbine engine, the blade having an airfoil that comprises oppositely-disposed convex and concave surfaces, oppositely-disposed leading and trailing edges defining therebetween a chord length of the airfoil, a forward-most nose of the airfoil located at the leading edge, and a blade tip, the process comprising:
placing the blade adjacent a coating material source in an apparatus configured to evaporate the coating material source and generate coating material vapors; and
depositing the erosion-resistant coating on at least the concave surface but not on the convex surface within at least 20% of the chord length from the nose.

18. The process according to claim 17, wherein the depositing step comprises simultaneously depositing the erosion-resistant coating on at least two blades, and the nose of at least a first of the blades is masked by a trailing edge of at least one adjacent blade.

19. The process according to claim 18, wherein the depositing step further comprises masking the convex surfaces of the blades to avoid deposition of the erosion-resistant coating on the convex surfaces.

20. The process according to claim 17, wherein the coating material source is evaporated and deposited by a physical vapor deposition process.
